(19) United States
(12) Patent Application Publication
(10) Pub. No.: US 2005/0253641 A1
(43) Pub. Date: Nov. 17, 2005

(54) Circuit with at least one delay cell

(75) Inventor: Udo Karthaus, Ulm (DE)

Correspondence Address: BIRCH STEWART KOLASCH & BIRCH, PO BOX 747, FALLS CHURCH, VA, 22040-0747, US

(73) Assignee: ATMEL Germany GmbH

(21) Appl. No.: 11/130,280

(22) Filed: May 17, 2005

(30) Foreign Application Priority Data
May 17, 2004 (DE) DE 10 2004 025 38

(51) Int. Cl. G11C 11/00

(52) U.S. Cl. 327/261

(57) ABSTRACT

A circuit having at least one delay cell that reflects an input signal change in an output signal with a delay and that has at least two pairs of inverters, wherein the outputs of the inverters of each pair of inverters are connected to one another so that the connected outputs of a first pair of inverters form a first output of the delay cell and the connected outputs of a second pair form a second output. The circuit is characterized in that one input of each inverter is connected to its own input of the delay cell, separately from inputs of other inverters.

This nonprovisional application claims priority under 35 U.S.C. § 119(a) on German Patent Application No. DE 102004025386.2, which was filed in Germany on May 17, 2004, and which is herein incorporated by reference.

### BACKGROUND OF THE INVENTION

1. Field of the Invention

The present invention relates to a circuit with at least one delay cell that reflects an input signal change in an output signal with a delay and that has at least two pairs of inverters, wherein the outputs of the inverters of each pair of inverters are connected to one another so that the connected outputs of a first pair of inverters form a first output of the delay cell and the connected outputs of a second pair form a second output.

2. Description of the Background Art

Delay cells are used, for example, to produce electrical oscillations in a voltage-controlled or current-controlled oscillator or for delayed forwarding of an input signal change in a signal processing circuit.

A circuit is known from U.S. Pat. No. 5,300,898, which describes a variant of an asymmetric ring oscillator made of CMOS inverters. The ring oscillator has an odd number of delay cells, in particular three such cells, as oscillator cells. The cells are connected in a ring so that the signal of any desired cell is returned to this cell after an odd number of inversions, where a repeated inversion of the output signal of this cell is produced. As a result, a periodic oscillation, which is to say a periodic change in the output signal level of each cell, is established in the ring. In contrast, if one connects an even number of cells into a ring with the topology from U.S. Pat. No. 5,300,898, the inversion of a signal through a specific cell after traversal of the ring does not result in a repeated inversion in the specific cell. Thus, instead of a periodic oscillation occurring in the even-numbered structure, one of two possible stable states is established.

In the subject matter of U.S. Pat. No. 5,300,898, the cells have differential inverters in which a coupling between two inverters is implemented through common current sources. In this regard, a differential inverter is understood to mean a parallel circuit of individual inverters that receives differential input signals, for example a logic 1 for one inverter and a logic 0 for the other inverter, or vice versa. The one inverter represents a first input and output of an oscillator cell and the other inverter, located in parallel, represents a second input and output of the oscillator cell. According to U.S. Pat. No. 5,300,898, the oscillator cells are connected in a ring configuration, wherein the first (or respectively the second) input of each oscillator cell is connected to a first (or respectively second) output of a preceding oscillator cell. In a certain sense, this forms two chains, with a first chain corresponding to the signal flow through the first inputs and a second chain corresponding to the signal flow through the second inputs and outputs. In theory, with ongoing synchronous signal inversion in the two chains, complementary phases (e.g. 0, 1) of the transmitted signal thus arise after each oscillator cell.

Due to the current sources, the inverters are slower than if they were connected to fixed supply voltages. In order to still achieve adequately short delay times, transistors serving as current sources must be operated in the triode region in which they exhibit a linear resistance characteristic. To achieve high frequencies, the resistance of these current sources must be very low. However, the coupling of the parallel-connected inverters becomes ever less at a low resistance. Consequently, at high frequencies there is always the danger that the two inverter chains will not run synchronously.

Another example of an oscillator having symmetrical differential stages is illustrated in U.S. Publication No. 20030034850, which shows an implementation of the differential stages in BiCMOS technology (BiCMOS=combination of bipolar and CMOS technologies). However, such a differential stage is slower than an inverter since the gate drive voltage is lower. Moreover, the delay cells of such ring oscillators draw current continuously. The current draw is thus proportional to the number of delay cells. Since the voltage swing is small as a function of load resistance and current and does not lie in the center of the supply voltage, the signals in the ring are not CMOS-compatible. Thus, in order to couple out the signals, a somewhat more complicated circuit (generally a differential amplifier) is needed, which likewise draws current continuously.

WO 01/43274 A2 shows an oscillator in which bistable amplifiers as delay cells are connected together into an oscillator that permits different signals with mutually complementary phases to be coupled out.

In addition to such ring oscillators of symmetrical differential stages, asymmetrical (non-differential) ring oscillators with delay cells of CMOS inverters are also known. One variation of such a structure is known, for example, from DE 197 28 248, which corresponds to U.S. Pat. No. 5,963,102. These ring oscillators have only one ring and thus an odd number of phases, since an even number would require a like number of delay cells. In the case of an even number, the oscillator would then become stuck in one of two possible stable states. The separation between two signals with identical phase (e.g. 0 or 1) coupled out of the ring corresponds to two inverter propagation delays, with inverter propagation delay being interpreted here as the typical gate delay. The minimum separation between the phases is thus undesirably large.

### SUMMARY OF THE INVENTION

It is therefore an object of the present invention to provide a circuit having at least one delay cell, which circuit can be expanded by concatenating multiple such cells into a closed ring oscillator with very short delay times or phase differences of the signal at outputs of adjacent delay cells.

This object is attained in a circuit in that one input of each inverter can be connected to its own input of the delay cell, separately from inputs of the other inverters.

Since the connected outputs of the inverters of a pair can be driven through two separate inputs in accordance with the invention, the result is additional degrees of freedom in circuit designs having multiple delay cells. Thus, for example, signals tapped off at different points in a ring oscillator can be fed into the pair of inverters through the separate inputs. For example, the phase difference between the outputs of adjacent pairs of inverters can be shortened significantly by time-offset driving of the inputs.

The inverters can be implemented as CMOS inverters.

As compared to other inverters, CMOS inverters, which is to say inverters with complementary N-channel and P-channel field-effect transistors, reduce current consumption of the circuit, since CMOS logic elements such as inverters only consume noticeable amounts of current at a transition between two stable states, and operate practically without current between such transitions.

At least one output of the delay cell can be connected to an amplifier element.

Since an amplifier generally has a high input resistance and a low output resistance, this design has the advantage of reducing the effects that circuits connected to the output have on the signal generation in the delay cell.

Another example embodiment is characterized by an additional CMOS inverter as an amplifier element.

Additional CMOS inverters can easily be produced with the other CMOS inverters of the circuit through a CMOS process. In addition, the implementation of the amplifier elements used for coupling out the signal as CMOS inverters reduces the current consumption of the circuit, since the CMOS inverters only consume noticeable amounts of current during switching processes. As a result, to a first approximation the current consumption of the circuit does not increase when the number of inverters, and thus the number of signal phases, is increased.

The circuit can have a number of delay cells that is divisible by two and is greater than or equal to four, with inputs of at least one nth delay cell being connected to outputs of at least one n−1 modulo Nth and one n−2 modulo Nth delay cell, where N represents the number of delay cells.

This example embodiment realizes the advantages, mentioned above as possibilities, of controlling the output signal of the first delay cell by, for example, signals from two additional delay cells. In particular, it is possible in this way to achieve a small phase difference between signals that can be tapped off at the outputs of adjacent delay cells.

Alternatively, the at least four delay cells are connected to one another such that a first signal path through a first chain of inverters and a second signal path through a second chain of inverters are produced, wherein signals in both signal paths advance synchronously in opposite phase, and wherein inputs of inverters in the first chain belonging to an nth delay cell are connected to outputs of inverters of the first chain belonging to an n−2k+/−1 modulo Nth delay cell and are connected to outputs of inverters of the second chain belonging to an n−2k modulo Nth delay cell, where k is a natural number greater than or equal to 1.

In this embodiment as well, the output of a delay cell can be driven by two inputs with a time offset so that as a result a reduced phase difference is produced between signals coupled out after inverters of a chain. While in simple ring oscillators, a particular phase that appears at the output of a specific inverter is not repeated until the output of the next inverter but one, which is to say two inverter propagation delays later, in the embodiment with k=1, repetition occurs after only ⅔ of an inverter propagation delay. For values k>1, the separation between like phases is even smaller.

Further, at least four delay cells of the circuit can be combined into a ring oscillator.

A particular advantage of the invention is that a ring oscillator can also be implemented with an even number of delay cells that is greater than or equal to four. In contrast, the prior art is only capable of having ring oscillators with an odd number of delay cells. Since every delay cell with the features of the invention permits coupling out of two signals with complementary phases, the invention makes it possible to design ring oscillators which provide practically any even number of mutually phase-shifted signals with a minimum number of delay cells. In contrast, the prior art, which requires an odd number of delay cells to produce oscillation in the ring oscillator, provides only 6, 10, 14, . . . possibilities for coupling out signals if it is assumed that two signals can be coupled out per delay cell.

Also, at least one controllable source of electrical energy can be connected to the supply connections of at least one of the inverters.

As a result of the controllability of the electrical energy supply, the delay time of an individual inverter, and thus the frequency of the circuit, can be controlled in a simple manner. In this regard, the advantage of a largely linear relationship between control voltage or control current on the one hand, and the frequency of the ring oscillator on the other hand, has been demonstrated in conjunction with the aforementioned embodiments.

Additional preferred embodiments are characterized by at least one voltage source and/or current source as source of electrical energy.

As an alternative or in addition, it is preferred that either a single current source supplies all delay cells with electrical energy, or that each delay cell has its own current source for the electrical energy supply.

In this context, it has become evident that, in direct comparison with a current supply, a voltage supply produces better linearity between control action and frequency response.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 illustrates a circuit according to an embodiment of the present invention;

FIG. 2 illustrates a ring oscillator having four delay cells with an interior structure as in FIG. 1;

FIG. 3 shows the ring oscillator from FIG. 2 together with a generalized internal structure of the delay cells; and

FIG. 4 shows portions of input signals and a resulting output signal of a delay cell.

### DETAILED DESCRIPTION

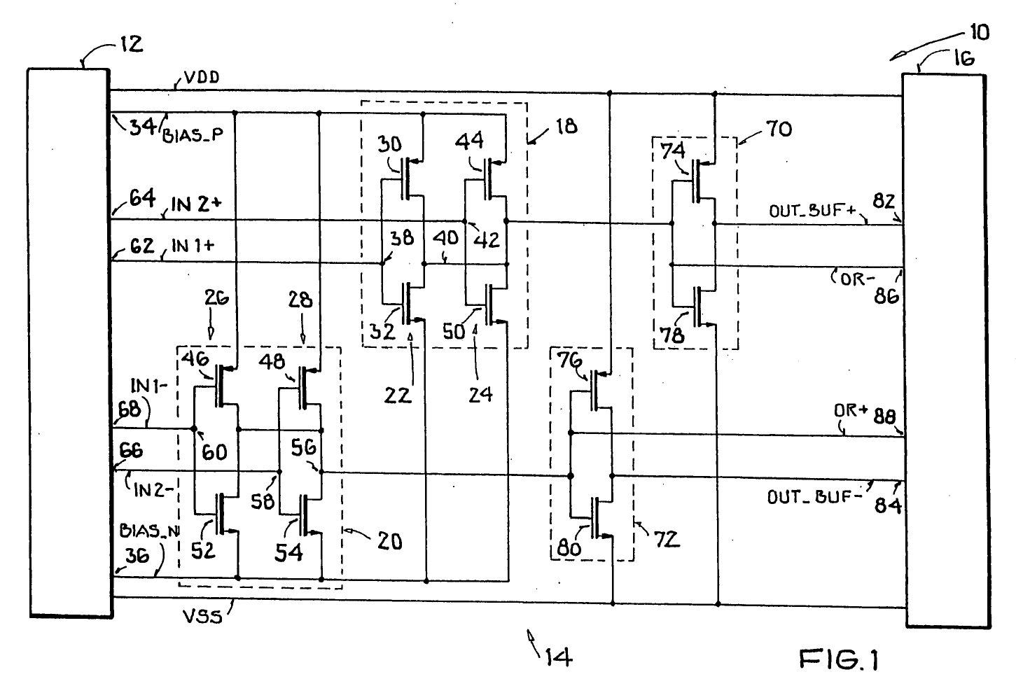

In particular, FIG. 1 shows a circuit 10 having an input circuit 12, a delay cell 14, and an output circuit 16. The delay cell 14 has two pairs 18, 20 of inverters 22, 24 and 26, 28. A first inverter 22 of the first pair 18 is preferably constructed as a CMOS inverter from a PMOS field-effect transistor 30 and an NMOS field-effect transistor 32 whose channels are located between a connection 34 with positive electrical potential BIAS_P and a connection 36 with negative electrical potential BIAS_N. When the gate connection 38, which serves as an input of the inverter 22, is driven with a positive potential, the channel of the NMOS transistor 32 conducts and the channel of the PMOS transistor 30 is turned off. As a result, the negative potential of the connection 36 is established at the output 40 of the inverter 22. Conversely, in the event of a negative potential at the gate connection 38, which results in a turned-off NMOS transistor 32 and conducting PMOS transistor 30, the positive potential of connection 34 is established at the output 40. Thus, the inverted gate potential or input signal is established in each case at the output 40, with the signal at the output 40 always following the signal at the input 38 with a delay caused by the transistor properties, which delay depends on the potential difference between the connections 34 and 36, for example.

The other inverters 24, 26, 28 are similarly constructed of PMOS transistors 44, 46, 48 and NMOS transistors 50, 52, 54 and operate in a corresponding manner. The inverter 24 of the first pair 18 thus inverts the input signal present at its input (gate) 42. Since the output of the inverter 24 is electrically connected to the output of the inverter 22 to form a common output 40, the potential at this output 40 can thus be influenced by one of the two inputs 38, 42 of the inverters 22, 24 at a time. A stable potential is then established at the output when both inverters are driven with signals of the same polarity. If the polarities are different, in contrast, a current flow through one conducting transistor of each of the two inverters and the common output can result.

In similar fashion, the potential at output 56 of the second pair 20 of inverters 26, 28 can be influenced by one of the two inputs 58, 60 of the inverters 28, 26 at a time. The input 38 of the inverter 22 is connected to its own input 62 of the delay cell 14, separately from the inputs 42, 58, 60 of the inverters 24, 26, 28. This applies analogously to the connections of one of the inputs 42, 58, 60 at a time of the inverters 24, 26, 28 to one separate input 64, 66, 68 of the delay cell 14. The input 62 is also referred to below as IN1+ input. In analogous fashion, the inputs 64, 66, 68 are also referred to as IN2+, IN2− and IN1− inputs, respectively.

For each output 40, 56 of the pairs 18, 20 of inverters 22, 24 and 26, 28, the delay cell 10 optionally has one amplifier element 70, 72 for coupling out signals at the outputs 40, 56. As a result of the amplifier elements 70, 72, which in the example embodiment in FIG. 1 are likewise implemented as CMOS inverters with PMOS transistors 74, 76 and NMOS transistors 78, 80, undesirable effects of impedances in the output circuit 16 on the signals at the outputs 40, 56 of the delay cell 14 are minimized. In the example embodiment in FIG. 1, signals OUT_BUF+, OUT_BUF−, which are to be coupled out and are inverted by the amplifiers 70 and 72, are passed to inputs 82, 84 of the output circuit 16, while the signals OR−, OR+, which are passed to inputs 86, 88 and are not inverted by the amplifiers 70, 72, can be forwarded to additional delay cells in the output circuit 16.

In the example embodiment in FIG. 1, the amplifier elements 70, 72 are supplied with energy by supply potentials VDD, VSS. The potentials at the connections 34 and 38 of the input circuit, with which the delay time of the inverters 22, 24, 26, 28 can be controlled, are also obtained within the input circuit 12 from these supply potentials VDD, VSS.

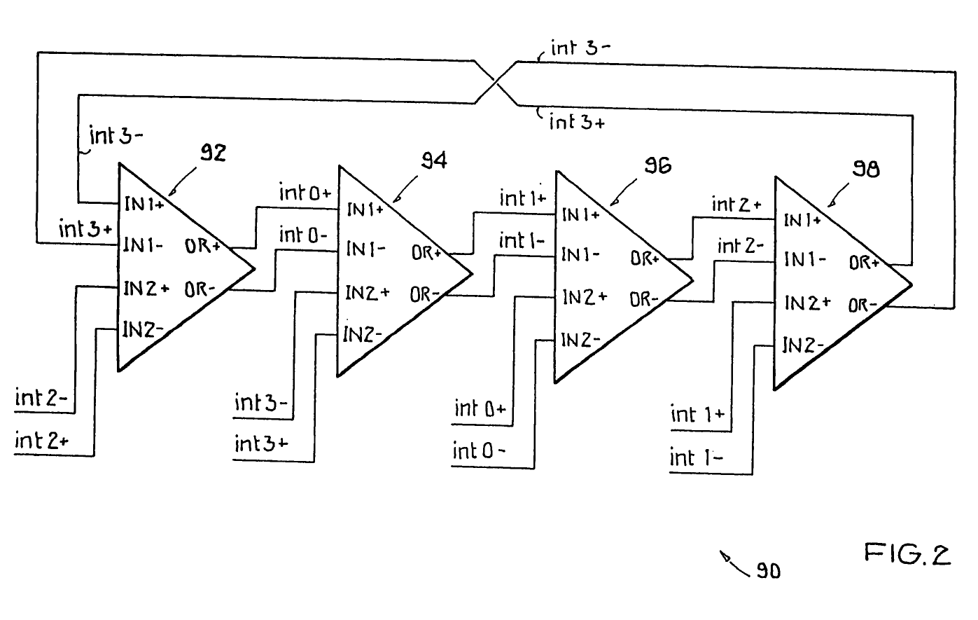

FIG. 2 shows a ring oscillator 90 with four delay cells 92, 94, 96, 98, each individual one of which has the structure with pairs of inverters and a common output described in connection with FIG. 1. For reasons of clarity, the representation of the energy supply and the signal output coupling is omitted in FIG. 2.

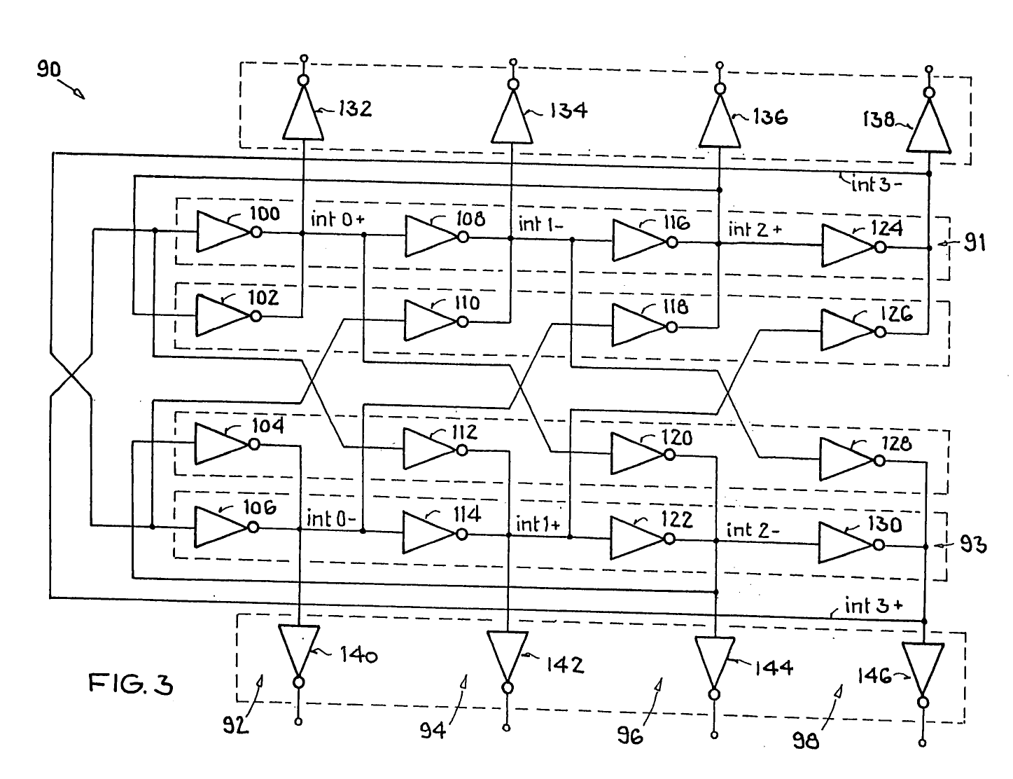

The 2nd delay cell 96 receives signals int1+, int1− from the first delay cell 94 arranged immediately ahead of it, and receives signals int0+ and int0− from the predecessor of delay cell 94, which is to say the 0th delay cell 92. Similarly, the 3rd delay cell 98 receives signals int2+ and int2− from its predecessor, the second delay cell 96, and receives signals int1+ and int1− from the predecessor of its predecessor, the 1st delay cell 94. The output signals int3+ and int3− of the third delay cell 98 and the output signals int2+ and int2− of the second delay cell 96 are each fed back crossed over to the 0th delay cell 92. The 1 st delay cell 94 is supplied with the output signals int0+ and int0− of the 0th delay cell 92, and with the crossed over output signals int3− and int3+ fed back from the third delay cell 98. This method of series connection of the delay cells 92, 94, 96 and 98 produces the ring oscillator 90, which has two chains 91, 93 in which signals with opposite phases propagate synchronously. A first chain 91 is represented by the signal path of the signals int0+, int1−, int2+ and int3−. Analogously, a second chain 93 results from the signal path of the signals int0−, int1+, int2− and int3+. This is more clearly evident in connection with FIG. 3.

FIG. 3 depicts the ring oscillator 90 from FIG. 2 together with an internal structure of the four delay cells 92, 94, 96, 98 in order to better explain the connection between FIGS. 1 and 2. Here, the CMOS inverters 22, 24, 26, 28, 70 and 72 of an individual delay cell 18 from FIG. 1 have been replaced in FIG. 3 by more general representations of inverters, such as can likewise be used in an implementation of the invention in a more general form.

In FIG. 3, the top two wired-together inverters 100, 102 of the cell 92 output the signal int0+, which corresponds to the signal OR+ from FIG. 1. According to FIG. 1, OR+ is supplied by the bottom inverter pair 20 in FIG. 1, whose outputs are wired together. The top two inverters 100, 102 of the cell 92 thus correspond in terms of signals to the bottom two inverters 26, 28 from FIG. 1. The two wired-together bottom inverters 104, 106 of the cell 92 in FIG. 2 output a signal int0− that corresponds to the signal OR− from FIG. 1 and is provided there by the top inverter pair 22, 24 whose outputs are wired together. The bottom inverters 104, 106 of the delay cell 92 thus correspond in terms of signals to the top two inverters 22 and 24 from FIG. 1.

The two wired-together top inverters 108, 110 of the delay cell 94 output int1−. According to FIG. 2, Int1− is obtained from the output OR−. According to FIG. 2, OR− is supplied by the top inverter pair 18, whose outputs are wired together. The top two inverters 108, 110 of the delay cell 94 thus correspond to the top two inverters 22, 24 from FIG. 1. The two wired-together bottom inverters 112, 114 of the delay cell 94 from FIG. 3 output int0+. According to FIG. 2, Int0+ is obtained from the output OR+. According to FIG. 1, OR+ is supplied by the bottom inverter pair 20, whose outputs are wired together. The bottom inverters of the delay cell 94 thus correspond to the bottom two inverters 26, 28 from FIG. 1.

The two wired-together top inverters 116, 118 of the delay cell 96 output int2+. According to FIG. 2, Int2+ is supplied by the output OR+, which is to say from the bottom inverter pair 20 from FIG. 1. The top two inverters 116, 118 of the delay cell 96 thus correspond to the bottom two inverters 26, 28 from FIG. 1. The two wired-together bottom inverters 120, 122 of the delay cell 96 from FIG. 3 output int2−. According to FIG. 2, Int2− is obtained from the output OR−. According to FIG. 1, OR− is supplied by the top inverter pair 18. The bottom inverters 120, 122 of the delay cell 96 thus correspond to the top two inverters 22, 24 from FIG. 1.

The two wired-together top inverters 124, 126 of the delay cell 98 from FIG. 3 output int3−. According to FIG. 2, Int3− is obtained from the output OR−. According to FIG. 1, OR− is supplied by the top inverter pair 18. The top two inverters 124, 126 of the delay cell 98 thus correspond to the top two inverters 22, 24 from FIG. 1. The two wired-together bottom inverters 128, 130 of the delay cell 98 from FIG. 3 output int3+. According to FIG. 2, Int3+ is obtained from the output OR+. According to FIG. 1, OR+ is supplied by the bottom inverter pair 20. The bottom two inverters 128, 130 of the delay cell 98 in FIG. 3 thus correspond to the bottom two inverters 26, 28 from FIG. 1. The inverters 132, 134, 136, 138, 140, 142, 144, 146 serve to couple signals with different phases out of the ring 90, and thus correspond to the amplifier elements 70, 72 from FIG. 1.

As already mentioned above in connection with FIG. 2, this manner of series connection of the delay cells 92, 94, 96 and 98, produces two chains in which signals with opposite phases propagate synchronously. The first chain is represented by the signal path of the signals int0+, int1−, int2+ and int3−, and thus in a certain sense by the first row of transversely oriented inverters, which is to say by the inverters 100, 108, 116 and 124. Analogously, the second chain results from the signal path of the signals int0−, int1+, int2− and int3+, and hence from the fourth row of transversely oriented inverters, which is to say from the inverters 106, 114, 122 and 130. The first and the second chain run synchronously but with opposite phases, so that, for example, the amplifier 132 couples out the opposite phase to the amplifier 140, the amplifier 134 couples out the opposite phase to the amplifier 142, the amplifier 136 couples out the opposite phase to the amplifier 144, and the amplifier 138 couples out the opposite phase to the amplifier 146. The coupling of the two chains, which ensures that both chains run synchronously, is implemented by the additional inverters 102, 104, 110, 112, 118, 120, 126 and 128, each inverter having its input connected to one chain and its output connected to the other chain.

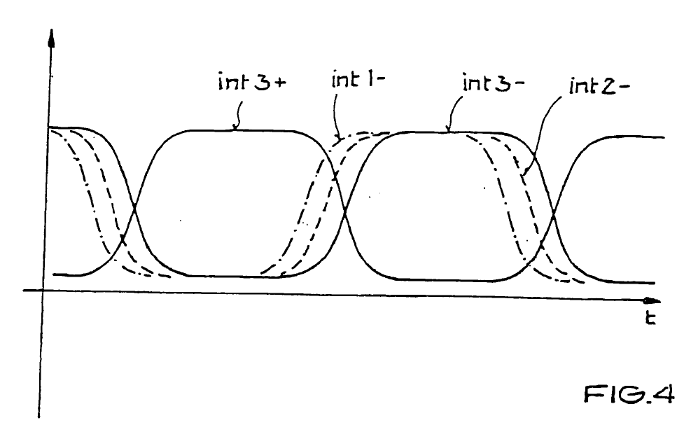

The circuit topology from FIG. 2 and/or FIG. 3 has the result that the input signals of each two inverters whose outputs are connected together differ only slightly in their phase, as is qualitatively shown in FIG. 4.

FIG. 4 shows portions of the input signal int3+ of the 3rd delay cell 98 from FIG. 2 or FIG. 3. Its input signals are the output signals int1− of the 1st delay cell 94 and int2− of the 2nd delay cell 96, whose edges overlap to a great degree. Consequently, the two inverters 128, 130 of the delay cell 98, which output int3+, do not work against one another, but instead work together with a slight time offset. In addition, a speed advantage thus results, because every delay cell with index n reacts not only to the signal output by the immediately preceding delay cell with index n−1 modulo N, but also reacts to the signal of the cell before the preceding delay cell with index (n−2) modulo N. This sharply reduces the separation between adjacent phases. In normal, asymmetrical ring oscillators, the same phase, for example 1 or 0, reappears after two inverters so that the separation in time corresponds to the sum of the signal propagation delays through both inverters. In contrast, in FIG. 4, which is based on an implementation with k=1, the separation between adjacent phases is only approximately 2/3 of the signal propagation delay of an inverter, so that the circuit is three times as fast as the normal ring oscillator. The speed advantage can be increased further by implementing circuit variants with k>1. Furthermore, FIG. 4 shows a portion of the signal int3−, which has a phase opposite to the signal int3+. The signals in FIG. 4 are each plotted over time in arbitrary units.

On the whole, the invention and its embodiments permit implementation of ring oscillators that provide an even number of clock signals of equal frequency and different phases and have a low current consumption independent of the number of phases, with very short, variable delay times or phase differences between the phases, and with tunable frequency. In this context, the frequency is preferably set by the supply voltage of the inverters, since the relationship between voltage and frequency is approximately linear, whereas in the case of frequency control through control currents, the current rises disproportionately at very high frequencies. It is a matter of course that the control can take place at the positive supply to the inverters in the ring, at the negative supply, or at both supplies. Moreover, the control can take place with one voltage source or current source for all delay cells. Alternatively, it can take place with separate current sources within each cell (current bank). As a further alternative, frequency control can also take place through variable capacitances, which undergo charge exchange as a function of the output signal of an inverter. It is also a matter of course that in place of a closed ring, an open ring, which is to say a chain of delay cells as in FIG. 1, may be used in order to generate different delayed versions (phases) of an input signal.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

1. A circuit having at least one delay cell that reflects an input signal change in an output signal with a delay, the delay cell includes at least two pairs of inverters, outputs of the inverters of each pair of inverters are connected to one another so that the connected outputs of first connected inverters form a first output of the delay cell and the connected outputs of second connected inverters form a second output,
wherein an input for each inverter is connected to its own respective input of the delay cell, thereby being separate from inputs of the other inverters.

2. The circuit according to claim 1, wherein each of the inverters are CMOS inverters.

3. The circuit according to claim 1, wherein at least one output of the delay cell is connected to an amplifier element.

4. The circuit according to claim 3, wherein the amplifier element is an inverter.

5. The circuit according to claim 1, wherein the circuit has a number N of delay cells that is divisible by two and is greater than or equal to four, wherein inputs of at least one nth delay cell are connected to outputs of at least one n−1 modulo Nth and one n−2 modulo Nth delay cell.

6. The circuit according to claim 1, wherein at least four delay cells are connected to one another such that a first signal path through a first chain of inverters and a second signal path through a second chain of inverters is formed, wherein signals in the two signal paths advance synchronously in opposite phase, and wherein inputs of inverters in the first chain, belonging to an nth delay cell, are connected to outputs of inverters of the first chain, belonging to an (n−2k+/−1) modulo Nth delay cell and are connected to outputs of inverters of the second chain belonging to an (n−2kth) modulo N delay cell, where k is a natural number greater than or equal to 1.

7. The circuit according to claim 1, wherein at least four delay cells are connected to one another to thereby form a ring oscillator.

8. The circuit according to claim 1, wherein at least one source of electrical energy is connected to supply connections of at least one of the inverters.

9. The circuit according to claim 8, wherein the source of electrical energy is provided by at least one voltage source and/or current source.

10. The circuit according to claim 9, wherein the at least one current source supplies all of the delay cells with electrical energy.

11. The circuit according to claim 9, wherein each delay cell has its, own respective current source.

12. A delay cell comprising:
a first inverter unit having a first pair of inverters, outputs of the first pair of inverters being connected to one another to thereby provide a first output signal; and
a second inverter unit having a second pair of inverters, outputs of the second pair of inverters being connected to one another to thereby provide a second output signal,
wherein each inverter of the first pair of inverters and the second pair of inverters is provided with an input signal that is different from one another.

13. The delay cell according to claim 12, wherein a plurality of delay cells are connected to one another such that the first inverter unit from a succeeding delay cell receives the second output signal from a preceding delay cell, and such that the second inverter unit from the succeeding delay cell receives the first output signal from the preceding delay cell.

14. A method for delaying an input signal in a circuit, the method comprising the steps of:
providing a first delay cell and a second delay cell, each delay cell having a first inverter unit having a first pair of inverters, outputs of the first pair of inverters being connected to one another to thereby provide a first output signal, a second inverter unit having a second pair of inverters, outputs of the second pair of inverters being connected to one another to thereby provide a second output signal;
connecting the first inverter unit from the second delay cell to receive the second output signal from the first delay cell;
connecting the second inverter unit from the second delay cell to receive the first output signal from the preceding delay cell; and
controlling an input source, which is connected to at least one of the pairs of inverters of the delay cell, to thereby control a delay time of the inverter connected to the input source.
